(19) United States
(12) Patent Application Publication
(10) Pub. No.: US 2026/0156800 A1
(43) Pub. Date: Jun. 4, 2026

(54) THREE-DIMENSIONAL SEMICONDUCTOR DEVICE AND MANUFACTURING METHOD THEREFOR

(71) Applicant: CXMT Corporation, Hefei City (CN)

(72) Inventor: Wenjing CHEN, Hefei City (CN)

(73) Assignee: CXMT Corporation, Hefei City (CN)

(21) Appl. No.: 19/403,940

(22) Filed: Nov. 30, 2025

Related U.S. Application Data
(63) Continuation of application No. PCT/CN2025/128116, filed on Oct. 16, 2025.

(30) Foreign Application Priority Data
Dec. 3, 2024 (CN) 202411789035.8

(51) Int. Cl. H10B 12/00

(52) U.S. Cl. CPC H10B 12/30; H10B 12/03; H10B 12/05

(57) ABSTRACT

A three-dimensional semiconductor device and a manufacturing method therefor. The three-dimensional semiconductor device includes multiple semiconductor layers, multiple word lines, multiple bit lines, and multiple memory nodes. The multiple word lines are arranged at intervals in the vertical direction, and each include one pair of traces respectively located on two opposite surfaces of each of the semiconductor layers in the vertical direction. The traces include first portions and second portions that are arranged alternately. The size of the first portion is greater than the size of the second portion in the second horizontal direction. The bit lines extend in the vertical direction and are coupled to one end of each of the multiple semiconductor layers in the vertical direction. The three-dimensional semiconductor device can at least improve a current driving capability of a transistor, and reduce mutual interference between adjacent memory cells.

### CROSS-REFERENCE TO RELATED APPLICATIONS

This application is a continuation of International Patent Application No. PCT/CN2025/128116 filed on Oct. 16, 2025, which claims priority to Chinese Patent Application No. 202411789035.8 filed on Dec. 3, 2024. The disclosures of the above-referenced applications are hereby incorporated by reference in their entirety.

### TECHNICAL FIELD

Embodiments of the present disclosure relate to the field of semiconductor technologies, and in particular, to a three-dimensional semiconductor device and a manufacturing method therefor.

### BACKGROUND

The development of a memory seeks performance indicators such as high speed, high integration density, and low power consumption. With miniaturization of the structure size of a semiconductor device, a technical barrier encountered by an existing structure becomes increasingly obvious. Therefore, on the basis of the existing structure, more novel structures are developed, which are advantageous means to break existing technical barriers.

The appearance of a three-dimensional memory meets the foregoing requirements. However, a current driving capability of a memory array transistor existing in the three-dimensional memory is insufficient, and mutual crosstalk between adjacent memory cells caused by a passing-gate effect (PEG) affects performance of the device.

### SUMMARY

According to a first aspect of the embodiments of the present disclosure, a three-dimensional semiconductor device is provided, including multiple semiconductor layers, arranged at intervals in a first horizontal direction and a vertical direction, each of the semiconductor layers extending in a second horizontal direction intersecting the first horizontal direction; multiple word lines, arranged at intervals in the vertical direction, each of the word lines extending in the first horizontal direction, and each of the word lines including one pair of traces respectively disposed on two opposite surfaces of each of the semiconductor layers in the vertical direction, where each of the traces includes multiple first portions and multiple second portions that are arranged alternately, and the size of the first portion is greater than the size of the second portion in the second horizontal direction; multiple bit lines, arranged at intervals in the first horizontal direction, each of the bit lines extending in the vertical direction, and each of the bit lines being coupled to one end of each of the multiple semiconductor layers in the vertical direction; and multiple memory nodes, each of the memory nodes being coupled to the other end of each of the semiconductor layers.

According to a second aspect of the embodiments of the present disclosure, a manufacturing method for a three-dimensional semiconductor device is provided, including: providing a substrate and forming a stacked layer in which multiple first sacrificial layers and multiple second sacrificial layers are alternately arranged on the substrate; forming a first perpendicular opening running through the stacked layer, the first perpendicular opening extending in a first horizontal direction; selectively etching the multiple second sacrificial layers in the stacked layer along the first perpendicular opening and forming multiple gate dielectric layers and multiple word lines, the multiple word lines being arranged at intervals in a vertical direction, and each of the word lines extending in the first horizontal direction and including one pair of traces, where each of the traces includes multiple first portions and multiple second portions that are arranged alternately, the size of the first portion is greater than the size of the second portion in a second horizontal direction, and the first horizontal direction intersects the second horizontal direction; filling the first perpendicular opening with a third sacrificial layer and forming multiple second perpendicular openings running through the third sacrificial layer, the multiple second perpendicular openings being arranged at intervals in the first horizontal direction; forming multiple bit lines arranged at intervals in the first horizontal direction respectively within the multiple second perpendicular openings, each of the bit lines extending in the vertical direction; forming a third perpendicular opening running through the stacked layer, the third perpendicular opening extending in the first horizontal direction; selectively etching the multiple first sacrificial layers in the stacked layer along the third perpendicular opening, and forming multiple memory nodes; forming multiple fourth perpendicular openings running through the stacked layer and located between the first perpendicular opening and the third perpendicular opening, the multiple fourth perpendicular openings being arranged at intervals in the first horizontal direction; and selectively etching remaining first sacrificial layers in the stacked layer respectively along the multiple fourth perpendicular openings, and forming multiple semiconductor layers arranged at intervals in the first horizontal direction and the vertical direction, each of the semiconductor layers being provided with one pair of traces respectively on two opposite surfaces in the vertical direction, and two ends of each of the semiconductor layers in the second horizontal direction being respectively coupled to the bit line and the memory node.

### BRIEF DESCRIPTION OF DRAWINGS

FIG. 1 is a schematic perspective view of a three-dimensional semiconductor device according to an example embodiment;

FIG. 2A is a local plane view of a three-dimensional semiconductor device according to an example embodiment;

FIG. 2B is a longitudinal sectional view taken along line A-A′ in FIG. 2A;

FIG. 3A is a plan view of a three-dimensional semiconductor device according to another embodiment of the present disclosure;

FIG. 3B is a longitudinal sectional view taken along line A-A′ in FIG. 3A;

FIG. 4 to FIG. 26 are schematic structural diagrams of stages in a manufacturing method for a three-dimensional semiconductor device according to an embodiment of the present disclosure; and

FIG. 27 is a schematic structural diagram of an electronic device according to an example embodiment.

### DESCRIPTION OF EMBODIMENTS

The technical solutions of the present disclosure are further described below in detail with reference to the accompanying drawings and the embodiments. It should be noted that the technical solutions described in the embodiments of the present disclosure may be arbitrarily combined when there is no conflict.

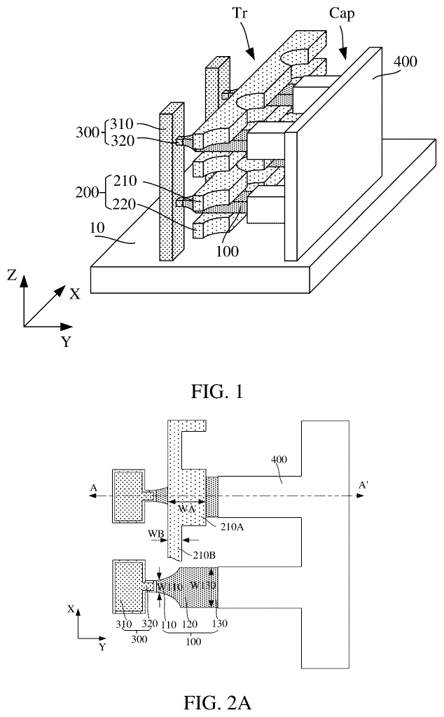

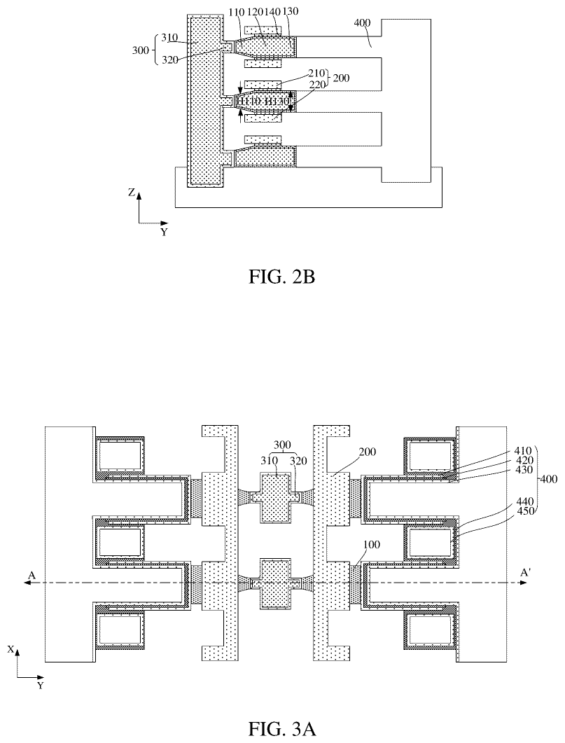

FIG. 1 is a schematic perspective view of a three-dimensional semiconductor device according to an example embodiment. FIG. 2A is a local plane view of a three-dimensional semiconductor device according to an example embodiment. FIG. 2B is a longitudinal sectional view taken along line A-A′ in FIG. 2A. Referring to FIG. 1 to FIG. 2B, a three-dimensional semiconductor device in an embodiment of the present disclosure includes a substrate 10 and a memory cell array having multiple memory cells, and includes multiple semiconductor layers 100, multiple word lines 200, multiple bit lines 300, and multiple memory nodes 400. These memory cells are arranged at intervals in a first horizontal direction X and a vertical direction Z on the substrate 10, that is, are arranged in a three-dimensional array. Each memory cell includes a transistor Tr and a memory node Cap that are coupled to each other in a second horizontal direction Y.

Still referring to FIG. 1, the substrate 100 includes, for example, silicon such as monocrystalline silicon, polysilicon, or amorphous silicon, and certainly may be selected from at least one of germanium (Ge), silicon germanium (SiGe), silicon carbide (SiC), gallium arsenide (GaAs), indium arsenide (InAs), and indium phosphide (InP).

Still referring to FIG. 1, the multiple semiconductor layers 100 are arranged at intervals in the first horizontal direction X and the vertical direction Z, and each semiconductor layer 100 extends in the second horizontal direction Y that intersects the first horizontal direction X. In some embodiments, every two of the first horizontal direction X, the second horizontal direction Y, and the vertical direction Z are perpendicular to each other. The multiple semiconductor layers 100 are isolated from each other via an isolation structure. The isolation structure may include at least one of silicon oxide, silicon nitride, or silicon oxynitride (a part of the isolation structure is omitted in FIG. 1), so that the multiple semiconductor layers 100 are arranged in a three-dimensional array on the substrate 10, and the multiple memory cells are arranged in a three-dimensional array.

Still referring to FIG. 1 and FIG. 2A, the semiconductor layer 100 may form an active region of the transistor Tr, and the semiconductor layer 100 includes a first source/drain region 110, a channel region 120, and a second source/drain region 130 that are arranged sequentially in the second horizontal direction Y. The first source/drain region 110 and the second source/drain region 130 are respectively located on two ends of the semiconductor layer 100. The semiconductor layer 100 further has two opposite surfaces in the vertical direction Z.

The semiconductor layer 100 is made of a semiconductor material, such as monocrystalline silicon, polysilicon, germanium, silicon germanium, or a metal oxide semiconductor material, such as at least one of indium tin oxide (ITO), indium gallium zinc oxide (IGZO), indium zinc oxide (IZO), and indium gallium oxide (IGO). In some embodiments, an insulating dielectric layer may be provided, such as a composite layer of silicon oxide, aluminium oxide, and a metal oxide semiconductor material, and the metal oxide semiconductor material surrounds a surface of the insulating dielectric layer and may operate at a relatively small operating current.

Still referring to FIG. 1 and FIG. 2B, the three-dimensional semiconductor device further includes multiple dielectric layers 140. The multiple dielectric layers 140 are arranged at intervals in the first horizontal direction X and the vertical direction Z. Each dielectric layer 140 is in contact with a corresponding semiconductor layer 100, and a gate dielectric layer of the transistor Tr may be formed. The dielectric layer 140 includes a pair of gate dielectric layers covering two opposite surfaces of the semiconductor layer 100 in the vertical direction Z, for example, covering at least the channel region 120 in the semiconductor layer 100, and the dielectric layer has a relatively flat surface. In this embodiment, the multiple dielectric layers 140 are disposed the same as the semiconductor layers 100. Certainly, in another embodiment, each dielectric layer in the multiple dielectric layers 140 may extend in the first horizontal direction X, and continuously contact multiple semiconductor layers 100 in the first horizontal direction X.

The material of the dielectric layer 140 may be selected from at least one of silicon oxide, silicon nitride, silicon oxynitride, and a high-k dielectric film with a higher dielectric constant greater than that of silicon oxide, for example, hafnium oxide (HfO₂), hafnium silicate (HfSiO), hafnium nitrogen oxide (HfON), hafnium silicon nitrogen oxide (HfSiON), hafnium aluminum oxide (HfAlO₃), lanthanum oxide (LaO), aluminum lanthanum oxide (LaAlO), and zirconium oxide (ZrO).

Still referring to FIG. 1 to FIG. 2B, the multiple word lines 200 are arranged at intervals in the vertical direction Z, each word line 200 extends in the first horizontal direction X, and each word line 200 is in contact with the gate dielectric layer, and is disposed on a corresponding semiconductor layer to form a gate electrode of the transistor Tr. Each word line 200 includes one pair of traces 210 and 220 respectively located on two opposite surfaces of each semiconductor layer 100 in the vertical direction Z, so that the word line 200 is referred to as a horizontal double word line or a horizontal double gate.

Still referring to FIG. 1 and FIG. 2B, a pair of traces 210 and 200 are symmetrically distributed to each other about the semiconductor layer 100, and the two form a pair and are coupled to one memory cell. Each of a pair of traces, such as the trace 210, includes multiple first portions 210A and multiple second portions 210B that are alternately arranged. The size WA of the first portion 210A is greater than the size WB of the second portion 210B in the second horizontal direction Y. The first portion 210A is in contact with the gate dielectric layer, and is disposed on the semiconductor layer 100 to form a gate portion of the transistor Tr, so as to ensure electrical performance of the transistor. The second portion 210B is located between two adjacent semiconductor layers 100 in the first horizontal direction X. Multiple relatively wide first portions 210A form a trace extending in the first horizontal direction X with relatively narrow second portions 210B. In this embodiment of the present disclosure, with a horizontal double word line in which the size WA of the first portion 210A is greater than the size WB of the second portion 210B, a current driving capability of a memory array transistor of a three-dimensional memory can be improved, and mutual interference between adjacent memory cells caused by a passing-gate effect (PGE) can be reduced. In some embodiments, the width WA of the first portion 210A in the second horizontal direction Y may be greater than or equal to the width of the dielectric layer 140.

The material of the word line 200 may be selected from at least one of doped polysilicon, metal, metal nitride, or metal carbide, for example, tungsten (W), molybdenum (Mo), titanium (Ti), tantalum (Ta), titanium nitride (TiN), tungsten nitride (WN), tantalum nitride (TaN), titanium aluminum nitride (TiAlN), tantalum aluminum nitride (TaAlN), titanium aluminum carbide (TiAlC), titanium aluminum carbonitride (TiAlCN), titanium silicon carbonitride (TiSiCN), tantalum aluminum carbonitride (TaAlCN), and tantalum silicon carbonitride (TaSiCN). In some embodiments, the word line 200 is, for example, titanium nitride.

Still referring to FIG. 1 and FIG. 2B, the multiple bit lines 300 are arranged at intervals in the first horizontal direction X, and each bit line 300 extends in the vertical direction Z. As shown in FIG. 1, each bit line 300 is coupled to one end of each of the multiple semiconductor layers 100 in the vertical direction Z, for example, the first source/drain region 110 of the semiconductor layer 100. The bit line 300 includes a vertically extending cylinder 310 and multiple protrusions 320, and the multiple protrusions 320 are integrally formed with the cylinder 310 and arranged at intervals on the vertically extending cylinder 310. Each bit line 300 is in contact with the multiple semiconductor layers 100 in the vertical direction via the multiple protrusions 320.

The material of the bit line 300 may be selected from at least one of doped polysilicon, metal, metal nitride, or metal carbide, for example, tungsten (W), molybdenum (Mo), titanium (Ti), tantalum (Ta), titanium nitride (TiN), tungsten nitride (WN), tantalum nitride (TaN), titanium aluminum nitride (TiAlN), tantalum aluminum nitride (TaAlN), titanium aluminum carbide (TiAlC), titanium aluminum carbonitride (TiAlCN), titanium silicon carbonitride (TiSiCN), tantalum aluminum carbonitride (TaAlCN), and tantalum silicon carbonitride (TaSiCN). In this embodiment of the present disclosure, the bit line 300 may be a composite layer of polysilicon and titanium nitride, and titanium nitride is located on a surface of a polysilicon cylinder and surrounds the polysilicon cylinder. The materials of the multiple protrusions 310 of the cylinder 310 are the same.

Still referring to FIG. 1, each memory node in the multiple memory nodes 400 is coupled to the other end of each semiconductor layer 100, for example, the second source/drain region 130, that is, the memory node 400 and the bit line 300 are respectively disposed on two opposite ends of the semiconductor layer 100 in the second horizontal direction Y. The memory node 400 may be a cylindrical or columnar capacitor, and may be selected according to an actual requirement. More specific embodiments will be described later in the present disclosure.

Referring back to FIG. 1 and FIG. 2A, in some embodiments of the present disclosure, in the first horizontal direction X, the size W110 of a semiconductor layer on one end close to the bit line 300 is less than the size W130 of a semiconductor layer on one end close to the memory node 400, that is, the width X of the first source/drain region 110 in the first horizontal direction may be less than the width of the second source/drain region 130 in the first horizontal direction X. Still referring to FIG. 1, in this case, for example, the first source/drain region 110 is in contact with the protrusion 320 of the bit line 300, and the protrusion 320 is located on the cylinder 310. The width of the protrusion 320 in the first horizontal direction X is less than the width of the cylinder 310. Further, in a direction toward the bit line 300, the width of the semiconductor layer 100 in the first horizontal direction X gradually decreases, and an end portion of the semiconductor layer 100 is in contact with the protrusion 320 of the bit line 300. The size of the second source/drain region 130 may be the same as the size of the channel layer 120, and the semiconductor layer 100 extends into contact with the memory node 400 in the second horizontal direction Y. The morphology of the semiconductor layer 100 toward one end of the bit line 300 is narrowed, so that the distance between adjacent bit lines in the first horizontal direction X can be increased, a directly facing area of the bit line 300 in the vertical direction can be reduced, and a coupling capacitance between the bit lines can be reduced.

Referring back to FIG. 1 and FIG. 2B, in still some other embodiments of the present disclosure, in the vertical direction Z, the size H110 of a semiconductor layer on one end close to the bit line 300 is less than the size H130 of a semiconductor layer on one end close to the memory node 400, that is, the height of the first source/drain region 110 in the vertical direction Z may be less than the height of the second source/drain region 130 in the vertical direction Z. Still referring to FIG. 2B, the first source/drain region 110 is in contact with the protrusion 320 of the bit line 300. For example, in the direction toward the bit line 300, the height of the semiconductor layer 100 in the vertical direction Z gradually decreases, and an end portion of the semiconductor layer 100 is in contact with the protrusion 320 of the bit line 300. The size of the second source/drain region 130 may be the same as the size of the channel layer 120, and the semiconductor layer 100 extends into contact with the memory node 400 in the second horizontal direction Y. The morphology of a semiconductor layer 100 toward one end of the bit line 300 is thinned. The distance between the bit line and the word line in the vertical direction Z can be increased, and a coupling capacitance between the bit line and the word line can be reduced.

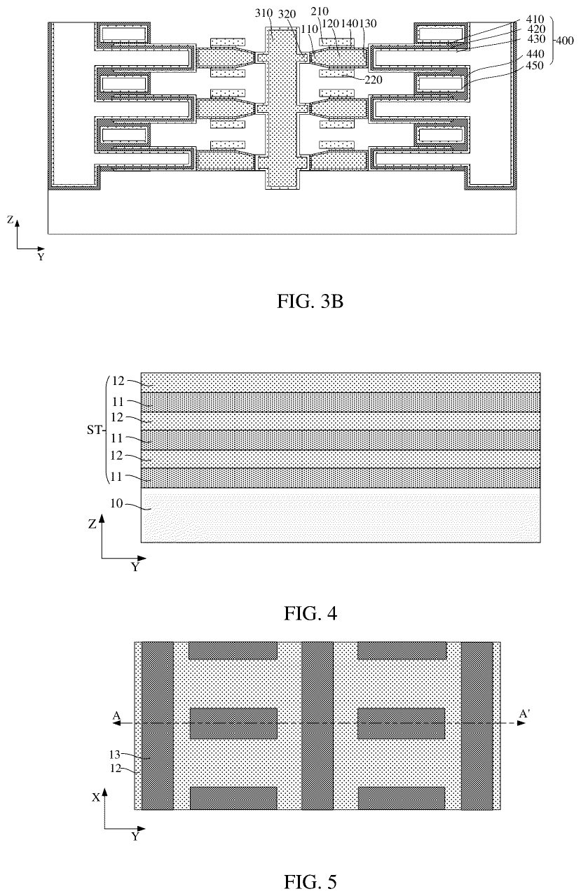

FIG. 3A is a plan view of a three-dimensional semiconductor device according to another embodiment of the present disclosure. FIG. 3B is a longitudinal sectional view taken along line A-A′ in FIG. 3A. Referring to FIG. 3A and FIG. 3B, the present disclosure provides more specific embodiments of the memory node 400. In this embodiment, the memory node 400 is a cylindrical capacitor, and the multiple memory nodes 400 include multiple bottom electrodes 410, a first capacitor dielectric layer 420, and a first top electrode 430. The multiple bottom electrodes 410 are arranged at intervals in the first horizontal direction X and the vertical direction Z, and respectively coupled to one end of multiple corresponding semiconductor layers 110, and each bottom electrode 410 includes two opposite surfaces. The bottom electrode 410 is of a U-shaped cylindrical shape extending in the second horizontal direction Y. The first capacitor dielectric layer 420 is located on surfaces of the multiple bottom electrodes 410, for example, may conformally cover an inner surface and an outer surface of the U-shaped cylindrical bottom electrode. The first top electrode 430 is located on a surface of the first capacitor dielectric layer 420. The first top electrode 430 is an entirety, and leads out signals of the multiple memory nodes 400.

Still referring to FIG. 3A and FIG. 3B, further, the multiple memory nodes 400 may further include a second capacitor dielectric layer 440 and a second top electrode 450. In this case, the first capacitor dielectric layer 420 is located on one surface of each of the multiple bottom electrodes 410, for example, the inner surface of the U-shaped cylindrical bottom electrode, the second capacitor dielectric layer 440 is located on the other surface of each of the multiple bottom electrodes 410, for example, the outer surface of the U-shaped cylindrical bottom electrode, and the second capacitor dielectric layer 440 is further located on the surface of the first capacitor dielectric layer 420 that is not covered by the bottom electrode 410, and is connected to the first capacitor dielectric layer 420. The second top electrode 450 is located on a surface of the second capacitor dielectric layer 450. The second top electrode 450 is an entirety. The second top electrode 450 and the first top electrode 430 are connected in series with each other, and a storage capacity of the memory node can be increased.

The material of the bottom electrode 410 may be selected from at least one of metal, metal nitride, or metal oxide, such as tungsten (W), molybdenum (Mo), titanium (Ti), tantalum (Ta), platinum (Pt), iridium (Ir), titanium nitride (TiN), tungsten nitride (WN), tantalum nitride (TaN), iridium oxide (IrO₂), and titanium oxide (TiO).

The material of the first capacitor dielectric layer 420 and the material of the second capacitor dielectric layer 440 may be separately selected from at least one of a high-k dielectric film with a higher dielectric constant greater than that of silicon oxide, for example, hafnium oxide (HfO₂), hafnium silicate (HfSiO), hafnium nitrogen oxide (HfON), hafnium silicon nitrogen oxide (HfSiON), hafnium aluminum oxide (HfAlO₃), lanthanum oxide (LaO), aluminum lanthanum oxide (LaAlO), and zirconium oxide (ZrO).

The material of the first top electrode 430 and the material of the second top electrode 450 may be separately selected from at least one of doped polysilicon, metal, metal nitride, or metal oxide, such as tungsten (W), molybdenum (Mo), titanium (Ti), tantalum (Ta), platinum (Pt), iridium (Ir), titanium nitride (TiN), tungsten nitride (WN), tantalum nitride (TaN), iridium oxide (IrO₂), and titanium oxide (TiO). In some embodiments, the top electrode includes a composite layer of polysilicon and titanium nitride, the polysilicon layer is in contact with titanium nitride, and the multiple memory nodes 400 lead out signals via polysilicon in the top electrode.

Still referring to FIG. 3A and FIG. 3B, the three-dimensional semiconductor device includes not only multiple memory cells arranged at intervals in the first horizontal direction X and the vertical direction Z, but also multiple memory cells arranged at intervals in the second horizontal direction Y, so that the three-dimensional semiconductor device further includes multiple memory cell arrays arranged at intervals in the second horizontal direction Y. Each memory cell array includes the multiple semiconductor layers 100, the multiple word lines 200, the multiple bit lines 300, and the multiple memory nodes 400 described in FIG. 1, FIG. 2A, and FIG. 2B. Adjacent memory cell arrays are mirror-symmetrical with respect to the bit line 300, that is, the bit line 300 is shared between adjacent memory cell arrays. In addition, adjacent memory cell arrays are mirror-symmetrical with respect to the top electrode of the memory node 400, that is, the top electrode is shared between adjacent memory cell arrays. For example, in this embodiment, the first top electrode 430 is shared.

In the embodiments shown in FIG. 3A and FIG. 3B, two memory cell arrays that are formed in the second horizontal direction Y and that are mirror-symmetrical to each other are described as examples. It may be understood that the two memory cell arrays that are mirror-symmetrical to each other are arranged repeatedly to obtain a three-dimensional semiconductor device with a higher storage density.

An embodiment of the present disclosure further provides a manufacturing method for a three-dimensional semiconductor device. FIG. 4 to FIG. 26 are schematic structural diagrams of stages in a manufacturing method for a three-dimensional semiconductor device according to an embodiment of the present disclosure.

In this embodiment of the present disclosure, for example, two memory cell arrays are formed in a second horizontal direction Y and are mirror-symmetrical to each other. It may be understood that more memory cell arrays may be formed at the same time. The memory cell arrays are arranged at intervals on a substrate 10, and the memory cell arrays may be isolated from each other via an isolation layer (not all shown) to protect the three-dimensional semiconductor device. With reference to FIG. 4 to FIG. 26, the following describes in detail the manufacturing method for a three-dimensional semiconductor device according to an embodiment of the present disclosure.

FIG. 4 shows a longitudinal sectional view of a stage in the manufacturing method for a three-dimensional semiconductor device. Referring to FIG. 5, a substrate 10 is provided, and a stacked layer ST in which multiple first sacrificial layers 11 and multiple second sacrificial layers 12 are alternately arranged is formed on the substrate 10. The first sacrificial layer 11 is, for example, silicon nitride, the second sacrificial layer 11 is, for example, silicon oxide, and there is an etching selectivity ratio between the first sacrificial layer 11 and the second sacrificial layer 12. Subsequently, the three-dimensional semiconductor device in the present disclosure may be formed by performing patterning and pattern filling on the first sacrificial layer 11 and the second sacrificial layer 12.

FIG. 5 shows a plan view of the three-dimensional semiconductor device at another stage in the manufacturing method for a three-dimensional semiconductor device. Referring to FIG. 5, the stacked layer ST is patterned to form multiple perpendicular openings running through the stacked layer ST, and separately form multiple third sacrificial layers 13 in the multiple perpendicular openings. Some third sacrificial layers in the multiple third sacrificial layers 13 extend in a first horizontal direction X, and remaining third sacrificial layers in the multiple third sacrificial layers are disposed on two sides of the third sacrificial layer in the first horizontal direction X, and are arranged at intervals in the first horizontal direction X. The third sacrificial layer is, for example, a polysilicon layer, which has a larger etching selectivity ratio than those of the first sacrificial layer 11 and the second sacrificial layer 12.

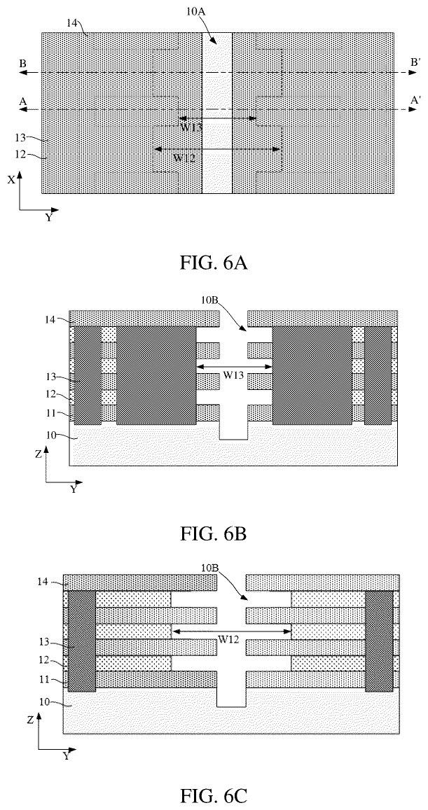

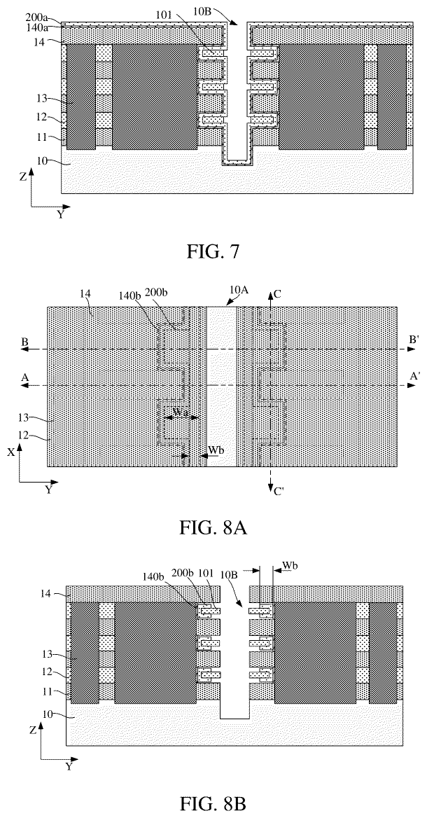

FIG. 6A shows a plan view of the three-dimensional semiconductor device at another stage in the manufacturing method for a three-dimensional semiconductor device. Referring to FIG. 6A to FIG. 6C, a first mask layer 14 is formed on a surface of the stacked layer ST. For example, the material of the first mask layer 14 is the same as that of the first sacrificial layer 11, and is silicon nitride. The first mask layer 14 is patterned, and one third sacrificial layer 13 extending in the first horizontal direction X in the multiple third sacrificial layers 13 is removed, to form a first perpendicular opening 10A running through the stacked layer ST. The first perpendicular opening 10A extends in the first horizontal direction X, and divides the stacked layer ST into multiple memory cell arrays arranged at intervals in a second horizontal direction Y. Then, a bit line 300 is formed in the first perpendicular opening 10A, so that adjacent memory cell arrays are mirror-symmetrical with respect to the bit line 300.

FIG. 6B and FIG. 6C show longitudinal sectional views taken along lines A-A′ and B-B′ of FIG. 6A, respectively. Still referring to FIG. 6A to FIG. 6C, some second sacrificial layers 12 in the stacked layer ST are etched laterally along the first perpendicular opening 10A. When the remaining third sacrificial layers 13 in the multiple sacrificial layers 13 are exposed, some second sacrificial layers 12 are continuously etched laterally to form a deposition space 10B with a first comb-like opening. The width of the deposition space 10B with the first comb-like opening is different in the first horizontal direction X, and the width W13 between two adjacent third sacrificial layers 13 in the second horizontal direction Y is less than the width W12 between two adjacent second sacrificial layers 12 in the second horizontal direction Y.

FIG. 7 shows a longitudinal sectional view taken along line A-A′ of FIG. 6A, which is a longitudinal sectional view of the three-dimensional semiconductor device at another stage in the manufacturing method for a three-dimensional semiconductor device after FIG. 6B. Referring to FIG. 7, a trace material is deposited in the deposition space 10B with the first comb-like opening along the first perpendicular opening 10A, that is, between the multiple first sacrificial layers 11 to form an initial gate dielectric layer 140a and an initial word line layer 200a. The initial gate dielectric layer 140a conformally covers surfaces of the first sacrificial layer 11, the second sacrificial layer 12, and the third sacrificial layer 13, and the surface of the first mask layer 14. The initial word line layer 200a covers a surface of the initial gate dielectric layer 140a. The initial word line layer 200a includes a first portion Wa and a second portion Wb. Then, still referring to FIG. 7, a first isolation layer material, such as silicon oxide, is filled in a remaining space of the deposition space 10B with the first comb-like opening along the first perpendicular opening 10A, and then the first perpendicular opening 10A is exposed again to remove the first isolation layer material in the first perpendicular opening 10A, so as to form multiple first isolation layers 101 arranged at intervals in the vertical direction Z, where the first isolation layer 101 is located between initial word line layers 200a and extends in the first horizontal direction X.

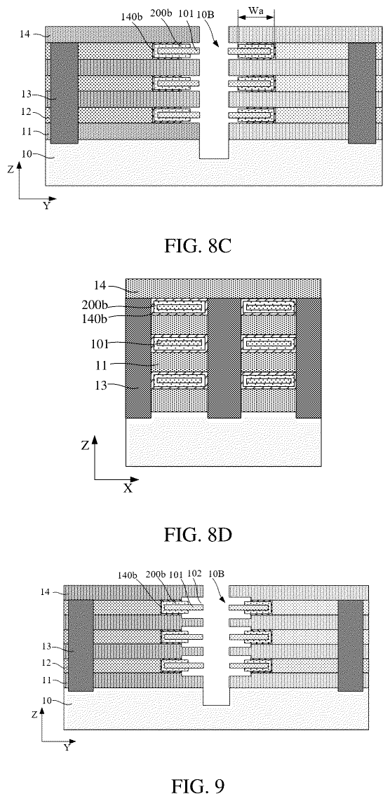

FIG. 8A shows a plan view of the three-dimensional semiconductor device at another stage in the manufacturing method for a three-dimensional semiconductor device. FIG. 8B to FIG. 8D show longitudinal sectional views taken along lines A-A′ and B-B′ of FIG. 8A, respectively. Referring to FIG. 8A to FIG. 8C, a part of the initial word line layer 200a is laterally etched continuously along the first perpendicular opening 10A, a part of the initial word line layer 200a exposed on a sidewall of the first perpendicular opening 10A is removed, and the initial word line layer 200a is disconnected to form multiple first intermediate word line layers 200b arranged at intervals in the vertical direction Z. Each first intermediate word line layer 200b extends in the second horizontal direction Y, and is of a U-shaped cylindrical shape in a horizontal orientation, with an opening toward the first perpendicular opening 10A. Still referring to FIG. 8A to FIG. 8C, in the first horizontal direction X, the width of each first intermediate word line layer 200b in the second horizontal direction Y includes the width Wa of a first portion and the width Wb of a second portion that are alternated, and the width Wa of the first portion is greater than the width Wb of the second portion. That is, the length of a cylinder wall of the first intermediate word line layer 200b in a U-shaped cylindrical shape has different widths at different locations. As shown in FIG. 8B, the first intermediate word line layer 200b is of a short U shape between two adjacent third sacrificial layers 13. As shown in FIG. 8C, the first intermediate word line layer 200b is of a long U shape between two adjacent second sacrificial layers 12 in the second horizontal direction Y. In this embodiment of the present disclosure, the width of an initial/intermediate word line layer in the first horizontal direction X is configured to ensure the morphology of a final word line layer and improve electrical performance of the device.

Still referring to FIG. 8B and FIG. 8C, a part of the initial gate dielectric layer 140a is laterally etched continuously along the first perpendicular opening 10A, and a part of the initial gate dielectric layer 140a exposed on a sidewall of the first perpendicular opening 10A, and a part between two adjacent third sacrificial layers 13 in adjacent second horizontal directions Y are removed to form multiple first intermediate gate dielectric layers 140b. The multiple first intermediate gate dielectric layers 140b are arranged at intervals in the first horizontal direction X and the vertical direction Z, and each intermediate gate dielectric layer 140b also has a U-shaped cylindrical shape in the horizontal orientation, with an opening toward the first perpendicular opening 10A. Still referring to FIG. 8B and FIG. 8C, the U-shaped cylindrical first intermediate gate dielectric layer 140b is located only between two adjacent second sacrificial layers 12 in the second horizontal direction, covers a part of an outer cylinder wall of the U-shaped cylindrical intermediate word line layer 200b, and is not located between two adjacent third sacrificial layers 13 in the second horizontal direction Y. Only a part of a cylindrical sidewall of the U-shaped cylindrical first intermediate gate dielectric layer 140b exists between two adjacent third sacrificial layers 13, and the first intermediate gate dielectric layers 140b are disconnected from each other in the first horizontal direction X.

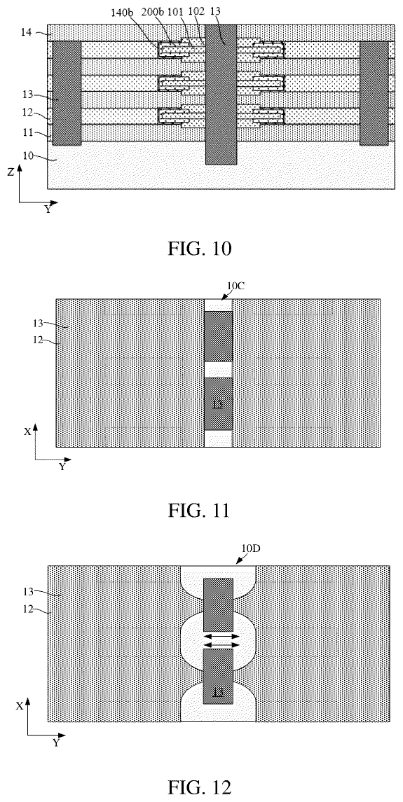

FIG. 9 shows a longitudinal sectional view taken along line B-B′ of FIG. 8A, which is a longitudinal sectional view of the three-dimensional semiconductor device at another stage in the manufacturing method for a three-dimensional semiconductor device after FIG. 8B. Referring to FIG. 9, in some embodiments of the present disclosure, two opposite surfaces of each of the multiple first sacrificial layers 11 in the stacked layer in the vertical direction Z are etched continuously along the first perpendicular opening 10A via a dry etching process, and the size of a first sacrificial layer 11 on one end close to the first perpendicular opening 10A in the vertical direction is thinned, thereby increasing a space in the vertical direction Z. In the vertical direction Z, the thickness of the first sacrificial layer 11 is inconsistent. More specifically, the distance between the intermediate word line layer 200b and the first sacrificial layer 11 is inconsistent. The thickness of a first sacrificial layer 11 on one end close to the first perpendicular opening 10A is relatively narrow, and the distance from the first intermediate word line layer 200b is longer, which provides a deposition space for subsequently forming the semiconductor layer 100.

FIG. 10 shows a longitudinal sectional view taken along line B-B′ of FIG. 8A, which is a section view of the three-dimensional semiconductor device at another stage in the manufacturing method for a three-dimensional semiconductor device after FIG. 9. A second isolation layer material, such as silicon oxide, is filled in the remaining space in the deposition space 10B with the first comb-like opening along the first perpendicular opening 10A, and then the first perpendicular opening 10A is exposed again to remove the second isolation layer material in the first perpendicular opening 10A to form multiple second isolation layers 102 arranged at intervals in the vertical direction Z. In addition, the third sacrificial layer 13 is filled in the first perpendicular opening 10A again, an entire surface is flattened, and surfaces of the third sacrificial layer 13 and the first mask layer 14 are flush with each other.

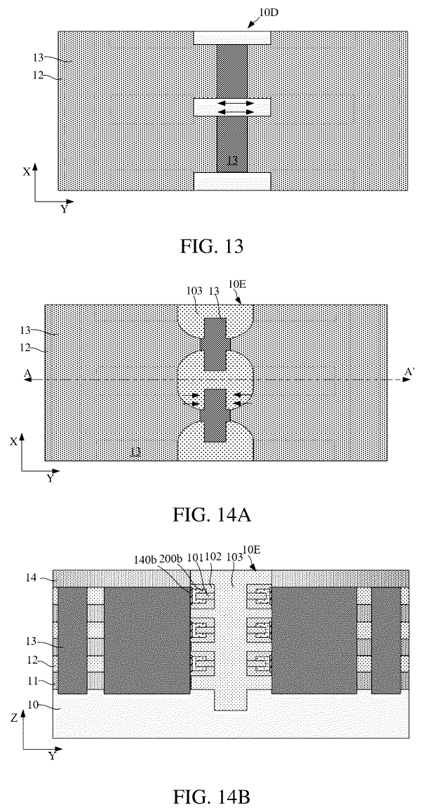

FIG. 11 shows a plan view of the three-dimensional semiconductor device at another stage in the manufacturing method for a three-dimensional semiconductor device. Referring to FIG. 11, in some embodiments of the present disclosure, before the bit lines 300 are formed, an isolation structure between the bit lines 300 may be first formed, which is not necessarily limiting. Still referring to FIG. 11, the first mask layer 14 is patterned to form multiple first vertical openings 10C running through the third sacrificial layer 13, and the multiple first vertical openings 10C and remaining third sacrificial layers 13 between the multiple first vertical openings 10C are arranged at intervals in the first horizontal direction X.

FIG. 12 shows a plan view of the three-dimensional semiconductor device at another stage in the manufacturing method for a three-dimensional semiconductor device. Referring to FIG. 12, some first sacrificial layers 11 are etched laterally along the multiple first vertical openings 100A to form a deposition space 10D of a second comb-like opening. The deposition space 10D of the second comb-like opening forms a ring-like opening in the first sacrificial layer 11 at each layer.

In some embodiments, the first sacrificial layer 11 may be etched via a wet etching process, and isotropic etching of the first sacrificial layer 11 may be controlled by controlling time, the composition of an etching solution, and an etching rate. The size of the first sacrificial layer 11 in the first horizontal direction X is inconsistent. Specifically, on one end close to the third sacrificial layer between the first vertical openings 10C, that is, on one end close to the subsequent second perpendicular opening 20A, the width of the first sacrificial layer 11 is relatively narrow, and the distance between adjacent first sacrificial layers 11 increases in the first horizontal direction X. After the semiconductor layer 100 is formed by replacing the first sacrificial layer, the size of the semiconductor layer 100 in contact with the bit line 300 is relatively small, which increases the distance between bit lines and reduces a coupling capacitance.

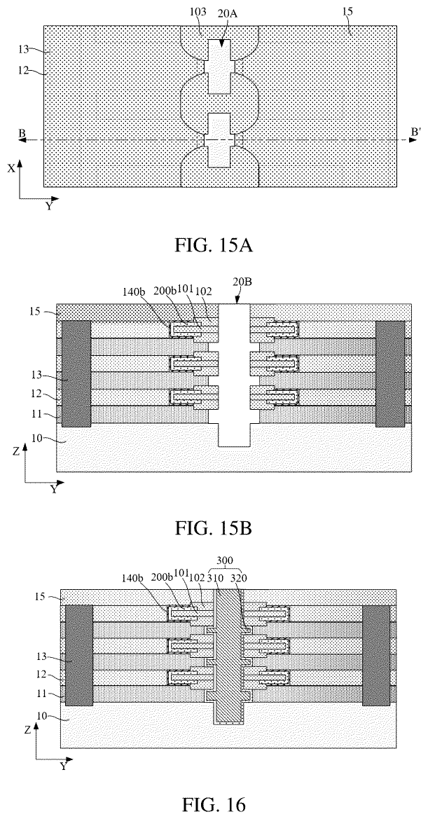

Certainly, in another embodiment, FIG. 13 shows a plan view of the three-dimensional semiconductor device at another stage in the manufacturing method for a three-dimensional semiconductor device according to another embodiment. As shown in FIG. 13, the first sacrificial layer 11 may alternatively be etched via a dry etching process. After dry etching, the second comb-like opening space 10D forms a rectangular opening in the first sacrificial layer 11 at each layer. In this embodiment, the size of the first sacrificial layer 11 in the first horizontal direction X is the same. Therefore, when the semiconductor layer 100 is formed by replacing the first sacrificial layer 11, the contact area between the semiconductor layer 100 and the bit line 300 is large, and a contact resistance therebetween is small.

FIG. 14A shows a plan view of the three-dimensional semiconductor device at another stage in the manufacturing method for a three-dimensional semiconductor device. FIG. 14B shows a longitudinal sectional view taken along line A-A′ of FIG. 14A. Referring to FIG. 14A and FIG. 14B, the third sacrificial layer 13 between the first vertical openings 10C is laterally etched continuously along the vertical opening 10C and the deposition space 10D of the second comb-like opening 10C to form a third comb-like deposition space 10E. In addition, a third isolation layer 103, such as silicon oxide, is filled in the third comb-like deposition space 10E, and the third isolation layer 103 is an isolation layer between multiple bit lines 300. In this case, the third isolation layer 103 is flush with the first mask layer 14.

Still referring to FIG. 14A and FIG. 14B, after the third comb-like deposition space 10E is formed and the third isolation layer 103 is deposited, a part of the third sacrificial layer 13 between the first vertical openings 10C is narrowed to form a vertically extending cylinder and multiple protrusions protruding from the cylinder. The multiple protrusions are in the same horizontal positions as the multiple first sacrificial layers 11, and are respectively in contact with corresponding first sacrificial layers 11, which preliminarily reserves a space for subsequently forming a bit line 300 including the cylinder 310 and the multiple protrusions 320.

FIG. 15A shows a plan view of the three-dimensional semiconductor device at another stage in the manufacturing method for a three-dimensional semiconductor device. FIG. 15B shows a longitudinal sectional view taken along line B-B′ of FIG. 15A. Referring to FIG. 15A and FIG. 15B, the first mask layer 14 is etched back and removed, and a second mask layer 15 is formed on a surface of the exposed stacked layer ST. The material of the second mask layer 15 may be the same as the material of the second sacrificial layer 12, for example, silicon oxide. Still referring to FIG. 15A and FIG. 15B, the second mask layer 15 is patterned, the third sacrificial layer 13 between the multiple first vertical openings 10C is removed to form multiple second perpendicular openings 20A, and the multiple second perpendicular openings 20A are arranged at intervals in the first horizontal direction X. Then, the multiple first sacrificial layers 11 in the stacked layer are selectively etched along the multiple second perpendicular openings 20A to form multiple deposition spaces 20B with a fourth comb-like opening arranged at intervals in the first horizontal direction X. In this process, the contact area between the second perpendicular opening 20A and the first sacrificial layer 11 is increased, and a space is further reserved for forming a bit line 300 including the cylinder 310 and the multiple protrusions 320.

FIG. 16 shows a longitudinal sectional view taken along line B-B′ of FIG. 15A, which is a longitudinal sectional view of the three-dimensional semiconductor device at another stage in the manufacturing method for a three-dimensional semiconductor device after FIG. 15B. Referring to FIG. 16, multiple bit lines 300 are formed in the multiple deposition spaces 20B with the fourth comb-like opening respectively along the multiple second perpendicular openings 20A, and the multiple bit lines 300 are arranged at intervals in the first horizontal direction X. In an embodiment of the present disclosure, the bit line 300 includes a composite layer of titanium nitride and polysilicon. Titanium nitride is located on a surface of polysilicon and surrounds polycrystalline silicon. Specifically, referring to FIG. 16, a titanium nitride layer is first deposited in the deposition space 20B with the fourth comb-like opening along the second perpendicular opening 20A, and the titanium nitride layer conformally covers surfaces of the second mask layer 15, the first isolation layer 101, the second isolation layer 102, the third isolation layer 103, the first sacrificial layer 11, and the second sacrificial layer 12. Polysilicon is also located in the fourth comb-like deposition space 20B, is located on a surface of the titanium nitride layer, and fills the remaining space of the fourth comb-like deposition space 20B. As shown in FIG. 16, the bit line 300 includes a vertically extending cylinder 310 and multiple protrusions 320, and the multiple protrusions 320 are integrally formed with the cylinder 310 and arranged at intervals on the vertically extending cylinder 310. In this case, multiple protrusions 320 of each bit line 300 are respectively in contact with multiple first sacrificial layers 11 in the vertical direction.

In this embodiment of the present disclosure, two adjacent memory cell arrays are formed at the same time, and multiple bit lines 300 are shared between the two adjacent memory cell arrays, which are mirror-symmetrical with respect to the bit line 300.

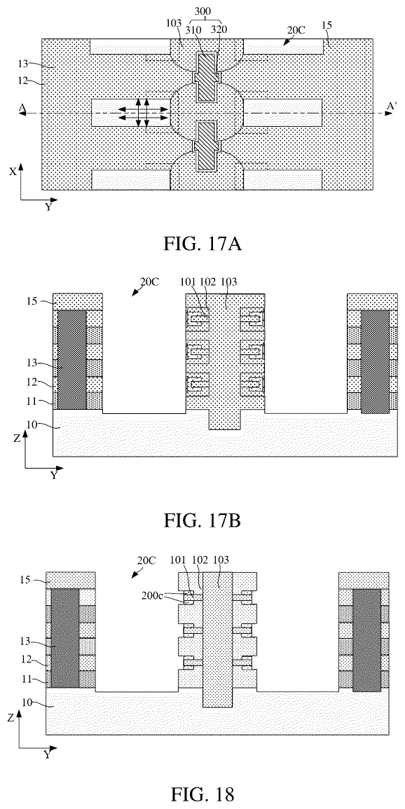

FIG. 17A shows a plan view of the three-dimensional semiconductor device at another stage in the manufacturing method for a three-dimensional semiconductor device. FIG. 17B shows a longitudinal sectional view taken along line A-A′ of FIG. 17A. Referring to FIG. 17A and FIG. 17B, multiple third sacrificial layers 13 separated in the first horizontal direction X are removed to form multiple second vertical openings 20C running through the stacked layer ST. The multiple second vertical openings 20C are arranged at intervals in the first horizontal direction X, and each second vertical opening 20C extends in the second horizontal direction Y, to expose the multiple first gate dielectric layers 140b and sidewalls of second portions Wb in the multiple first intermediate word line layers 200b arranged at intervals in the vertical direction Z.

FIG. 18 shows a longitudinal sectional view taken along line A-A′ of FIG. 17A, which is a section view of the three-dimensional semiconductor device at another stage in the manufacturing method for a three-dimensional semiconductor device after FIG. 17B. Referring to FIG. 18, the first intermediate gate dielectric layer 140b and the sidewall of the first intermediate word line layer 200b are selectively etched respectively along the multiple second vertical openings 20C to disconnect the first intermediate gate dielectric layer 140b and the first intermediate word line layer 200b at the second vertical openings 20C in the vertical direction Z to form multiple second intermediate gate dielectric layers 140c and multiple second intermediate word line layers 200c. In this case, the second intermediate gate dielectric layer 140c and the second intermediate word line layer 200c are disconnected in the vertical direction Z at the second portion Wb with a relatively narrow width, and the second intermediate gate dielectric layer 140c and the second intermediate word line layer 200c are still continuous in the vertical direction Z at the first portion Wa with a relatively wide width. In this case, as shown in FIG. 18, a short U-shaped sidewall in the second intermediate gate dielectric layer 140c is removed, and a long U-shaped sidewall is not removed. The second intermediate gate dielectric layers 140c are presented in multiple independent U-shaped cylinders and are arranged at intervals in the first horizontal direction X and the vertical direction Z, and each second intermediate gate dielectric layer 140c also has a U-shaped cylindrical shape in the horizontal orientation, with an opening toward the bit line 300.

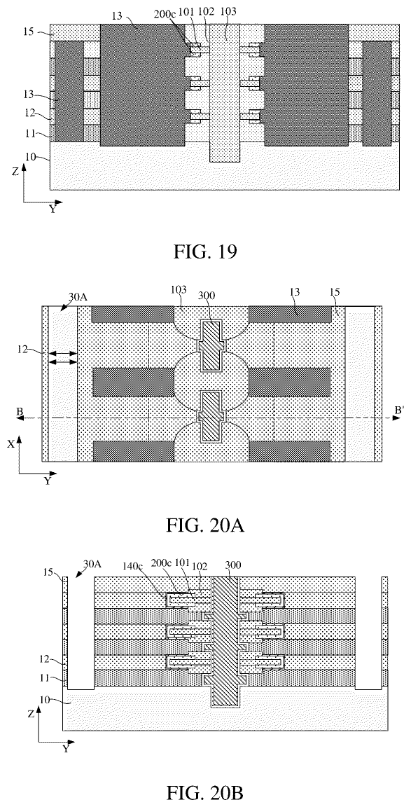

FIG. 19 shows a longitudinal sectional view taken along line A-A′ of FIG. 17A, which is a longitudinal sectional view of the three-dimensional semiconductor device at another stage in the manufacturing method for a three-dimensional semiconductor device after FIG. 18. Referring to FIG. 19, multiple third sacrificial layers 13 are respectively backfilled in multiple second vertical openings 20C. In this case, surfaces of the multiple third sacrificial layers 13 and the second mask layer 15 are flush with each other.

FIG. 20A shows a plan view of the three-dimensional semiconductor device at another stage in the manufacturing method for a three-dimensional semiconductor device. FIG. 20B shows a longitudinal sectional view taken along line B-B′ of FIG. 20A, which is a section view of the three-dimensional semiconductor device at another stage in the manufacturing method for a three-dimensional semiconductor device after FIG. 19. Referring to FIG. 20A and FIG. 20B, the second mask layer 15 is patterned, and a sacrificial layer 13 extending in the first horizontal direction X in the multiple third sacrificial layers 13 is removed, to form a third perpendicular opening 30A running through the stacked layer ST. The third perpendicular opening 30A extends in the first horizontal direction X.

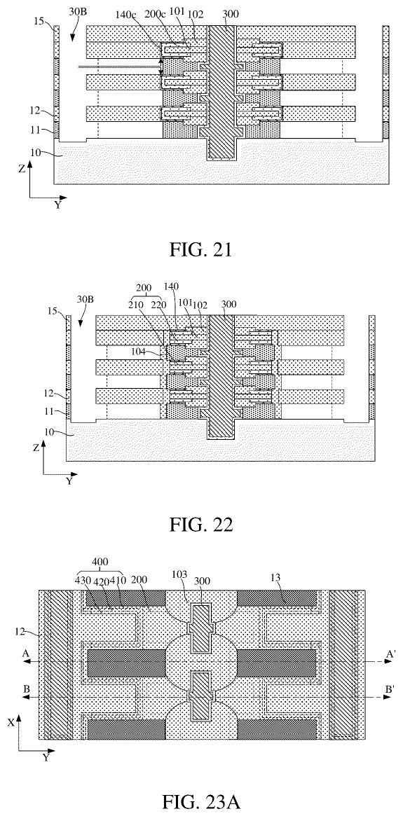

FIG. 21 shows a longitudinal sectional view taken along line B-B′ of FIG. 20A, which is a longitudinal sectional view of the three-dimensional semiconductor device at another stage in the manufacturing method for a three-dimensional semiconductor device after FIG. 20B. Referring to FIG. 21, some of the multiple first sacrificial layers 11 in the stacked layer are selectively etched along the third perpendicular opening 30A until a sidewall of the second intermediate gate dielectric layer 140C and a sidewall of the second intermediate word line layer 200c are exposed, to form a deposition space 30B with a fifth comb-like opening.

FIG. 22 shows a longitudinal sectional view taken along line B-B′ of FIG. 20A, which is a section view of the three-dimensional semiconductor device at another stage in the manufacturing method for a three-dimensional semiconductor device after FIG. 21. Referring to FIG. 22, in the vertical direction Z, the sidewalls of the second intermediate gate dielectric layer 140c and the second intermediate word line layer 200c are sequentially etched, and the second intermediate gate dielectric layer 140c and the second intermediate word line layer 200c that are continuous at the first portion Wa with a relatively wide width are disconnected in the vertical direction Z, to form a gate dielectric layer 140 and a word line 200.

Still referring to FIG. 22 and back to FIG. 2A and FIG. 2B, the word line 200 extends in the first horizontal direction, and each word line 200 includes one pair of traces 210 and 220, each of the traces 210 and 220 includes multiple first portions 210A and multiple second portions 210B that are arranged alternately, and the size WA of the first portion is greater than the size WB of the second portion in the second horizontal direction Y. The gate dielectric layer 140 includes a pair of gate dielectric layers, and the pair of gate dielectric layers are located between the first portion 210A and the first sacrificial layer 11. After the remaining first sacrificial layer 11 is replaced with the semiconductor layer 100, the gate dielectric layer 140 is located between the semiconductor layer 100 and the word line 200, a pair of gate dielectric layers covers two opposite surfaces of the semiconductor layer 100 in the vertical direction Z, and a pair of traces 210 and 220 respectively cover surfaces of the pair of gate dielectric layers, so that the pair of traces 210 and 220 are respectively located on two opposite surfaces of the semiconductor layer 100 in the vertical direction Z. Then, still referring to FIG. 22, a fourth isolation layer 104 is filled in a gap between the word line 200 and the second sacrificial layer 12 along the third perpendicular opening 30A.

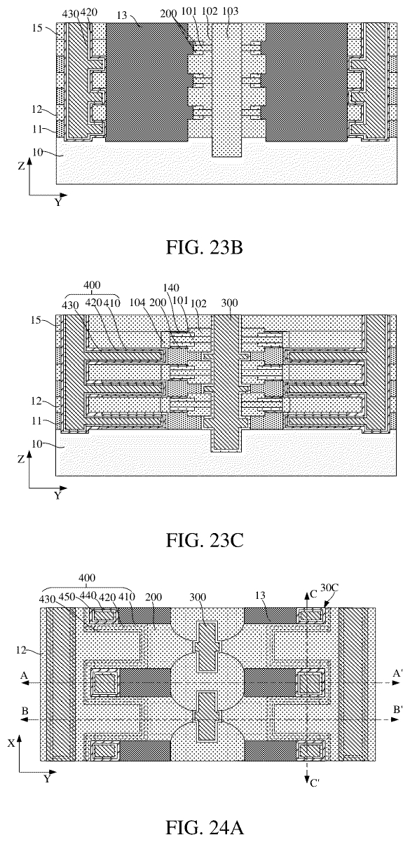

FIG. 23A shows a plan view of the three-dimensional semiconductor device at another stage in the manufacturing method for a three-dimensional semiconductor device. FIG. 23B and FIG. 23C show longitudinal sectional views taken along lines A-A′ and B-B′ of FIG. 23A, respectively. Referring to FIG. 23A to FIG. 23C, multiple memory nodes 400 are formed in the deposition space 30B with the fifth comb-like opening along the third perpendicular opening 30A. The multiple memory nodes 400 are in contact with the multiple first sacrificial layers 11. In some embodiments of the present disclosure, the multiple memory nodes 400 include multiple bottom electrodes 410, a first capacitor dielectric layer 420, and a first top electrode 430. Specifically, a bottom electrode material is deposited between the multiple second sacrificial layers 12 along the third perpendicular opening 30A, and the bottom electrode material is located on surfaces of the first sacrificial layer 11 and the second sacrificial layer 12. Then, the bottom electrode material exposed in the third perpendicular opening 30A is removed along the third perpendicular opening 30A, to form multiple bottom electrodes 410 arranged at intervals in the first horizontal direction X and the vertical direction Z. The multiple bottom electrodes 410 are of a U-shaped cylindrical shape in the horizontal orientation, with an opening toward the third perpendicular opening 30A. The multiple bottom electrodes 410 in the vertical direction Z are isolated from each other via the second sacrificial layer 12. The multiple bottom electrodes 410 in the first horizontal direction X are isolated from each other via the third sacrificial layer 13. A U-shaped cylinder sidewall of each bottom electrode 410 is in contact with one first sacrificial layer 11, and the U-shaped cylinder sidewall is located in a space enclosed by two second sacrificial layers 12 and two third sacrificial layers 13.

Then, still referring to FIG. 23A to FIG. 23C, a first capacitor dielectric layer 420 is formed in the fifth comb-like deposition space 40B continuously along the third perpendicular opening 30A. The first capacitor dielectric layer 420 is located on a cylindrical inner wall surface of the U-shaped cylindrical bottom electrode 410. Further, as shown in FIG. 23C, the first capacitor dielectric layer 420 is a continuous layer, and is further located on surfaces of the second sacrificial layer 12 and the third sacrificial layer 13 that are not covered by the bottom electrode 410, and a surface exposed by the third perpendicular opening 30A.

Then, still referring to FIG. 23A to FIG. 23C, a first top electrode 430 is formed in the deposition space 30B with the fifth comb-like opening continuously along the third perpendicular opening 30A. The first top electrode is, for example, a composite layer of titanium nitride and polysilicon. For example, a titanium nitride layer may be conformally deposited on a surface of the first capacitor dielectric layer 420. Then, a polysilicon layer is deposited in a remaining space of the deposition space 30B with the fifth comb-like opening along the third perpendicular opening 30A to form the first top electrode 430. The first top electrode 430 is an integral layer, a first top electrode 430 in the third perpendicular opening 30A extends in the first horizontal direction X and runs through the stacked layer, and surfaces of the first top electrode 430 and the second mask layer 15 are flush with each other.

In this embodiment of the present disclosure, only multiple memory nodes connected to one memory cell array are shown. When multiple memory cell arrays are formed at the same time, multiple memory nodes 400 of two adjacent memory cell arrays may be formed at the same time, and the two are mirror-symmetrical with respect to the first top electrode 430.

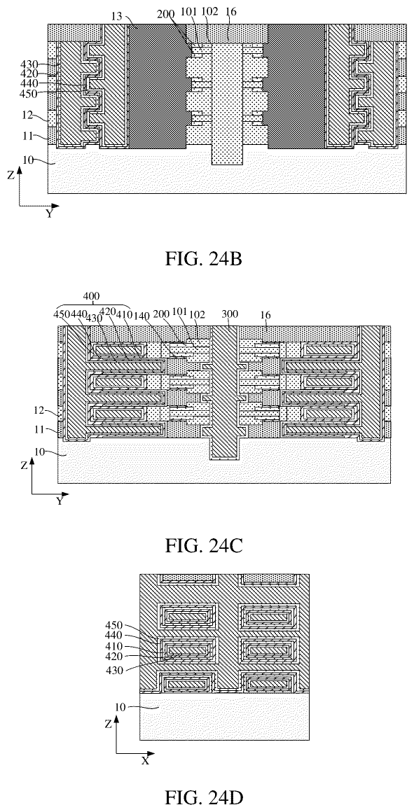

FIG. 24A shows a plan view of the three-dimensional semiconductor device at another stage in the manufacturing method for a three-dimensional semiconductor device. FIG. 24B to FIG. 24D show longitudinal sectional views taken along lines A-A′, B-B′, and C-C′ of FIG. 24A, respectively. In still some other embodiments of the present disclosure, to further increase a capacitance, a second top electrode may further be connected in series at the first top electrode 430. Specifically, referring to FIG. 24A to FIG. 24D, a third mask layer 16 is formed on the stacked layer ST, that is, on a surface common to the first top electrode 430 and the second mask layer 15, for example, may have the same material as the first sacrificial layer 11, for example, silicon nitride. Then, the third mask layer 16 is patterned, and some remaining third sacrificial layers 13 are removed, to form multiple third vertical openings 30C running through the stacked layer ST and located between the third perpendicular opening 30A and the multiple fourth perpendicular openings 40A, and the multiple third vertical openings 30C are arranged at intervals in the first horizontal direction X and the second horizontal direction Y. The multiple third vertical openings 30C arranged at intervals in the first horizontal direction X are located in a region between the word line 200 (or the first sacrificial layer 11) and the memory node 400. Then, still referring to FIG. 24A to FIG. 24D, the remaining second sacrificial layers 12 in the stacked layer are selectively etched respectively along the multiple third vertical openings 30C, and the other surface of each of the multiple bottom electrodes 410 is exposed to form a deposition space with a sixth comb-like opening. The sixth comb-like deposition space exposes the cylindrical outer wall surface the U-shaped cylindrical bottom electrode 410, and exposes a part of the first capacitor dielectric layer 420. Then, the second capacitor dielectric layer 440 and the second top electrode 450 are formed in sequence in the deposition space with the sixth comb-like opening respectively along the multiple third vertical openings 30C. Specifically, the second capacitor dielectric layer 440 is located on the cylindrical outer wall surface of the U-shaped cylindrical bottom electrode 410 and the surface of the first capacitor dielectric layer 420, and is connected to the first capacitor dielectric layer 420 as a whole. The second top electrode 450 is located on a surface of the second capacitor dielectric layer 440. The structure of the second top electrode 450 is the same as that of the first top electrode 430. In some embodiments, the second top electrode includes a composite layer of titanium nitride and polysilicon. A titanium nitride layer is deposited on the surface of the second capacitor dielectric layer 440, and then a polysilicon layer is deposited in the remaining space of the deposition space with the sixth comb-like opening separately along the multiple third vertical openings 30C, to form a second top electrode 450, where the second top electrode 450 is an integral layer and fills multiple third vertical openings 30C. The surface of the second top electrode 450 is flush with that of the third mask layer 16, and is higher than the surface of the first top electrode 430. Then, for example, the first top electrode 430 and the second top electrode 450 may be connected in series via a contact plug (not shown in the figure). Certainly, in some embodiments of the present disclosure, the first top electrode 430 and the second top electrode 450 may be connected in series together via a back end of line (BEOL), so as to save a process.

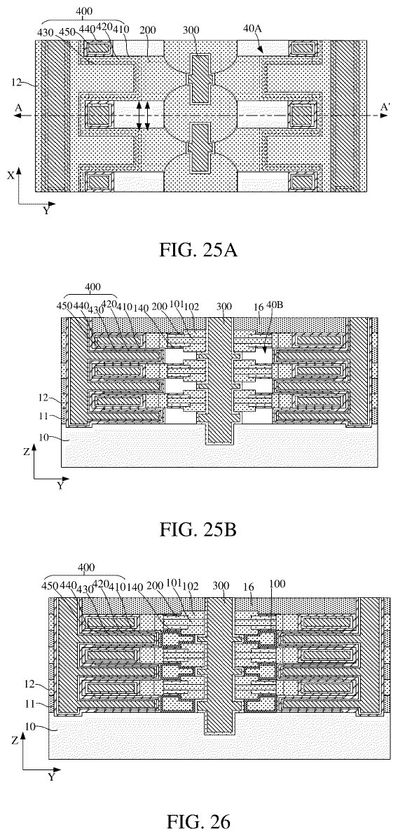

FIG. 25A shows a plan view of the three-dimensional semiconductor device at another stage in the manufacturing method for a three-dimensional semiconductor device. FIG. 25B shows a longitudinal sectional view taken along line A-A′ of FIG. 25A. Referring to FIG. 25A and FIG. 25B, the third mask layer 16 is patterned, and multiple remaining third sacrificial layers 13 are removed to form multiple fourth perpendicular openings 40A running through the stacked layer, which are located between the first perpendicular opening 10A and the third perpendicular opening 30A. The multiple fourth perpendicular openings 40A are arranged at intervals in the first horizontal direction X and the second horizontal direction Y. The multiple fourth perpendicular openings 40A arranged at intervals in the first horizontal direction X are located in a region between the bit line 300 and the memory node 400.

Still referring to FIG. 25A and FIG. 25B, the remaining first sacrificial layers 11 in the stacked layer are selectively etched respectively along the multiple fourth perpendicular openings 40A to form a deposition space 40B with a seventh comb-like opening. The deposition space 40B with the seventh comb-like opening exposes a surface of the projection 320 of the bit line 300, a surface of the word line 200, that is, surfaces of a pair of traces 210 and 220, and a surface of the bottom electrode 410 of the memory node 400.

FIG. 26 shows a longitudinal sectional view taken along line A-A′ of FIG. 25A, which is a section view of the three-dimensional semiconductor device at another stage in the manufacturing method for a three-dimensional semiconductor device after FIG. 25B. Referring to FIG. 26, a metal oxide semiconductor material, such as indium gallium zinc oxide (IGZO), and an insulating dielectric material, such as aluminium oxide, are deposited in the deposition space 40B with the seventh comb-like opening respectively along the multiple fourth perpendicular openings 40A via atomic layer deposition (ALD), to form a semiconductor layer material. Specifically, indium gallium zinc oxide may be continuously located in the fourth perpendicular openings 40A and surfaces of protrusions 320 of multiple bit lines exposed by the seventh comb-like deposition space 40B, surfaces of a pair of traces 210 and 220 of the multiple word lines, and surfaces of multiple first bottom electrodes 410. Aluminium oxide is located on a surface of indium gallium zinc oxide, is wrapped by indium gallium zinc oxide, and fills a remaining space of the deposition space 40B with the seventh comb-like opening.

Still referring to FIG. 26, and referring back to FIG. 1 to FIG. 3B, the fourth perpendicular opening 40A is exposed again to disconnect the semiconductor layer material to form multiple semiconductor layers 100 arranged at intervals in the first horizontal direction X and the vertical direction Z. A pair of traces 210 and 220 are respectively disposed on two opposite surfaces of the semiconductor layer 100 in the vertical direction Z, and two ends of the semiconductor layer 100 in the second horizontal direction Y are respectively coupled to the bit line 300 and the memory node 400. Then, a fifth isolation layer (not shown in the figure) is filled. The multiple semiconductor layers 100 in the first horizontal direction X are isolated from each other via the fifth isolation layer. The multiple semiconductor layers 100 arranged at intervals in the vertical direction Z are separated from each other via the first isolation layer 101 and the second isolation layer 102.

In the embodiments of the present disclosure, a three-dimensional semiconductor device is provided. A word line includes one pair of traces on two opposite surfaces of each semiconductor layer in the vertical direction, and each trace includes multiple first portions and multiple second portions that are arranged alternately. In an extending direction of the semiconductor layer, the size of the first portion is greater than the size of the second portion, and a three-dimensional semiconductor device structure of a double-gate field effect transistor is provided, which can significantly improve a current driving capability of a transistor, reduce impact of a passing-gate effect (PGE) on adjacent memory cells, and improve device performance.

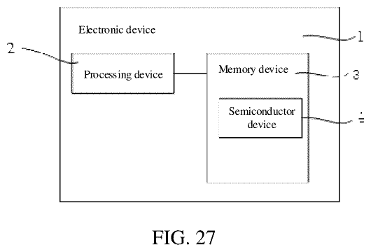

Referring to FIG. 27, an embodiment of the present disclosure further provides an electronic device 1 with a storage function. The electronic device includes a processing device 2 and a memory device 3 electrically connected to the processing device. The memory device includes the three-dimensional semiconductor device 4 described in FIG. 1 to FIG. 26. The electronic device may be a terminal device such as a personal computer (Personal Computer), a mobile phone (mobile phone), a tablet computer (pad), and a consumer electronics product (Consumer electronics) such as a smart home appliance, an automotive (automotive), a smart wearable product (such as a smart watch and a smart band), a virtual reality (virtual reality, VR) device, an augmented reality (augmented reality, AR) device, or a server (server), and a data center (data center). The memory device 3 may be, for example, a non-volatile dual in-line memory module (Non-Volatile Dual In-Line Memory Module, NVDIMM) or a storage class memory (Storage Class Memory, SCM) with high performance, high bandwidth, and high density. A storage function in the electronic device 1 may be implemented via the memory device 3.

In some embodiments, the processing device 2 and the memory device 3 may be two independent chips to form independent devices. In another embodiment, the processing device 2 and the memory device 3 may also be integrated into the same chip to form an embedded device. The electronic device 1 and the three-dimensional semiconductor device 4 described in FIG. 1 to FIG. 26 can resolve the same technical problem and achieve the same expected effects.

The foregoing descriptions are merely specific implementations of the present disclosure, but are not intended to limit the protection scope of the present disclosure. Any variation or replacement readily figured out by a person skilled in the art within the technical scope disclosed in the present disclosure shall fall within the protection scope of the present disclosure. Therefore, the protection scope of the present disclosure shall be subject to the protection scope of the claims.

1. A three-dimensional semiconductor device, comprising:
a plurality of semiconductor layers, arranged at intervals in a first horizontal direction and a vertical direction, each of the semiconductor layers extending in a second horizontal direction intersecting the first horizontal direction;
a plurality of word lines, arranged at intervals in the vertical direction, each of the word lines extending in the first horizontal direction, and each of the word lines comprising one pair of traces respectively disposed on two opposite surfaces of each of the semiconductor layers in the vertical direction, wherein each of the traces comprises a plurality of first portions and a plurality of second portions that are arranged alternately, and a size of the first portion is greater than a size of the second portion in the second horizontal direction;
a plurality of bit lines, arranged at intervals in the first horizontal direction, each of the bit lines extending in the vertical direction, and each of the bit lines being coupled to one end of each of the plurality of semiconductor layers in the vertical direction; and
a plurality of memory nodes, each of the memory nodes being coupled to the other end of each of the semiconductor layers.

2. The three-dimensional semiconductor device according to claim 1, wherein in the vertical direction, a size of a semiconductor layer on one end close to the bit line is less than a size of a semiconductor layer on one end close to the memory node.

3. The three-dimensional semiconductor device according to claim 1, wherein in the first horizontal direction, a size of a semiconductor layer on one end close to the bit line is less than a size of a semiconductor layer on one end close to the memory node.

4. The three-dimensional semiconductor device according to claim 2, wherein in the first horizontal direction, a size of a semiconductor layer on one end close to the bit line is less than a size of a semiconductor layer on one end close to the memory node.

5. The three-dimensional semiconductor device according to claim 1, wherein the plurality of memory nodes are cylindrical and comprise:
a plurality of bottom electrodes, arranged at intervals in the first horizontal direction and the vertical direction, and respectively coupled to one end of a plurality of corresponding semiconductor layers, each of the bottom electrodes comprising two opposite surfaces;
a first capacitor dielectric layer, located on one surface of each of the plurality of bottom electrodes;
a first top electrode, located on a surface of the first capacitor dielectric layer;
a second capacitor dielectric layer, located on the other surface of the plurality of bottom electrodes and connected to the first capacitor dielectric layer; and
a second top electrode, located on a surface of the second capacitor dielectric layer and connected in series to the first top electrode.

6. A manufacturing method for a three-dimensional semiconductor device, comprising:
providing a substrate and forming a stacked layer in which a plurality of first sacrificial layers and a plurality of second sacrificial layers are alternately arranged on the substrate;
forming a first perpendicular opening running through the stacked layer, the first perpendicular opening extending in a first horizontal direction;
selectively etching the plurality of second sacrificial layers in the stacked layer along the first perpendicular opening and forming a plurality of gate dielectric layers and a plurality of word lines, the plurality of word lines being arranged at intervals in a vertical direction, and each of the word lines extending in the first horizontal direction and comprising one pair of traces, wherein each of the traces comprises a plurality of first portions and a plurality of second portions that are arranged alternately, a size of the first portion is greater than a size of the second portion in a second horizontal direction, and the first horizontal direction intersects the second horizontal direction;
filling the first perpendicular opening with a third sacrificial layer and forming a plurality of second perpendicular openings running through the third sacrificial layer, the plurality of second perpendicular openings being arranged at intervals in the first horizontal direction;
forming a plurality of bit lines arranged at intervals in the first horizontal direction respectively within the plurality of second perpendicular openings, each of the bit lines extending in the vertical direction;
forming a third perpendicular opening running through the stacked layer, the third perpendicular opening extending in the first horizontal direction;
selectively etching the plurality of first sacrificial layers in the stacked layer along the third perpendicular opening, and forming a plurality of memory nodes;
forming a plurality of fourth perpendicular openings running through the stacked layer and located between the first perpendicular opening and the third perpendicular opening, the plurality of fourth perpendicular openings being arranged at intervals in the first horizontal direction; and
selectively etching remaining first sacrificial layers in the stacked layer respectively along the plurality of fourth perpendicular openings, and forming a plurality of semiconductor layers arranged at intervals in the first horizontal direction and the vertical direction, each of the semiconductor layers being provided with one pair of traces respectively on two opposite surfaces in the vertical direction, and two ends of each of the semiconductor layers in the second horizontal direction being respectively coupled to the bit line and the memory node.

7. The manufacturing method for a three-dimensional semiconductor device according to claim 6, further comprising:
etching, along the first perpendicular opening, two opposite surfaces of each of the plurality of first sacrificial layers in the stacked layer in the vertical direction via a dry etching process, and thinning a size of a first sacrificial layer on one end close to the first perpendicular opening in the vertical direction.

8. The manufacturing method for a three-dimensional semiconductor device according to claim 6, further comprising: after the filling the first perpendicular opening with a third sacrificial layer,
forming a plurality of first vertical openings running through the third sacrificial layer, the plurality of first vertical openings being arranged at intervals in the first horizontal direction;
etching the plurality of first sacrificial layers in the stacked layer respectively along the plurality of first vertical openings via a wet etching process, to narrow a size of a first sacrificial layer on one end close to the second perpendicular opening in the first horizontal direction;
removing the third sacrificial layer between the plurality of first vertical openings to form the plurality of second perpendicular openings;
selectively etching the plurality of first sacrificial layers in the stacked layer respectively along the plurality of second perpendicular openings, and increasing a contact area between the second perpendicular openings and the first sacrificial layers; and
respectively forming the plurality of bit lines in the plurality of second perpendicular openings.

9. The manufacturing method for a three-dimensional semiconductor device according to claim 7, further comprising: after the filling the first perpendicular opening with a third sacrificial layer,
forming a plurality of first vertical openings running through the third sacrificial layer, the plurality of first vertical openings being arranged at intervals in the first horizontal direction;
etching the plurality of first sacrificial layers in the stacked layer respectively along the plurality of first vertical openings via a wet etching process, to narrow a size of a first sacrificial layer on one end close to the second perpendicular opening in the first horizontal direction;
removing the third sacrificial layer between the plurality of first vertical openings to form the plurality of second perpendicular openings;
selectively etching the plurality of first sacrificial layers in the stacked layer respectively along the plurality of second perpendicular openings, and increasing a contact area between the second perpendicular openings and the first sacrificial layers; and
respectively forming the plurality of bit lines in the plurality of second perpendicular openings.

10. The manufacturing method for a three-dimensional semiconductor device according to claim 6, wherein the forming a plurality of word lines comprises:
depositing a trace material between the plurality of first sacrificial layers along the first perpendicular opening to form an initial word line layer, the initial word line layer comprising a first portion and a second portion;
removing, along the first perpendicular opening, a sidewall of the initial word line layer exposed within the first perpendicular opening to form a plurality of first intermediate word line layers arranged at intervals in the vertical direction;
forming a plurality of second vertical openings running through the stacked layer, each of the second vertical openings being exposed on a sidewall of a second portion of each of a plurality of first intermediate word line layers arranged at intervals in the vertical direction;
removing the sidewall of the second portion of each of the plurality of first intermediate word line layers respectively along the plurality of second vertical openings to form a plurality of second intermediate word line layers;
selectively etching the plurality of first sacrificial layers in the stacked layer along the third perpendicular opening until a sidewall of a first portion of each of the plurality of second intermediate word line layers is exposed; and
removing a sidewall of a first portion of each of the plurality of second intermediate word line layers along the third perpendicular opening to form the plurality of word lines, each of the word lines comprising one pair of traces.

11. The manufacturing method for a three-dimensional semiconductor device according to claim 6, wherein the forming a plurality of memory nodes comprises:
forming a plurality of bottom electrodes between the plurality of second sacrificial layers along the third perpendicular opening, the plurality of bottom electrodes respectively contacting one end of a plurality of corresponding first sacrificial layers;
forming a first capacitor dielectric layer on one surface of each of the plurality of bottom electrodes along the third perpendicular opening; and
forming a first top electrode on a surface of the first capacitor dielectric layer along the third perpendicular opening.

12. The manufacturing method for a three-dimensional semiconductor device according to claim 11, further comprising:
forming a plurality of third vertical openings running through the stacked layer and located between the third perpendicular opening and the plurality of fourth perpendicular openings, the plurality of third vertical openings being arranged at intervals in the first horizontal direction;
selectively etching remaining second sacrificial layers in the stacked layer along the plurality of third vertical openings, to expose the other surface of the plurality of bottom electrodes;
forming a second capacitor dielectric layer on the other surface of the plurality of bottom electrodes along the plurality of third vertical openings, the second capacitor dielectric layer being further located on the first capacitor dielectric layer; and
forming a second top electrode on a surface of the second capacitor dielectric layer respectively along the plurality of third vertical openings, and serially connecting the first top electrode and the second top electrode.
